(19) United States
(12) Patent Application Publication
(10) Pub. No.: US 2007/0290204 A1
(43) Pub. Date: Dec. 20, 2007

(54) SEMICONDUCTOR STRUCTURE AND METHOD FOR MANUFACTURING THEREOF

(76) Inventors: Jui-Meng Jao, Miaoli County (TW); Chien-Li Kuo, Hsinchu (TW); Hui-Ling Chen, Kaohsiung County (TW); Pao-Chuan Chen, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,062

(22) Filed: Jun. 15, 2006

(51) Int. Cl. H01L 23/58

(52) U.S. Cl. 257/48

(57) ABSTRACT

The invention is directed to a semiconductor structure located on a substrate in a scribe line region of a wafer. The semiconductor structure comprises a first dielectric layer, a first test pad and a passivation layer. The first dielectric layer is disposed on the substrate and the first test pad is disposed on the first dielectric layer. The passivation layer is disposed on the first dielectric layer and surrounding the first test pad and a groove is located between the first test pad and the passivation layer and the groove is at lest located between the boundary of the scribe line region and the first test pad.

### BACKGROUND OF THE INVENTION

1. Field of Invention

The present invention relates to a semiconductor structure and a method for manufacturing thereof. More particularly, the present invention relates to a semiconductor structure and a method for manufacturing therefore in which a film layer on a scribe line is prevented from being delaminated during a wafer cutting process.

2. Description of Related Art

With the development of the technology, the semiconductor industry becomes one of the most important industries. However, in order to full fill different requirements, the manufacturing process of the semiconductor becomes more and more complicated. Therefore, it is not easy to produce chips with high yield and low cost.

To obtain the real-time information showing whether the manufacturing process is successfully performed or not during the manufacturing process of the semiconductor chip, several test keys are designed to be disposed at the peripheral region of the chip, which is the scribe lines parallel to or perpendicular to each other, and are connected to several test pads respectively for being tested. Hence, each stage of the manufacturing process can be monitored.

After the devices on the wafer are manufactured, a passivation layer is formed over the wafer to protect the devices from being damaged by the moisture and other contaminants and the passivation layer only exposes the pads on the scribe lines of the wafer.

FIG. 1 is a cross-sectional view showing a conventional semiconductor structure located on the scribe line. As shown in FIG. 1, a dielectric layer 102 is located on the substrate 100 in a scribe region. Within the dielectric layer 102, there are interconnects for the testing purpose or other device structures (not shown) and these interconnects or other device structures can be electrically connected to the test pad 104 over the dielectric layer 102 so that the operator can use probe or other method to inspect the interconnects or other device structures within the dielectric layer 102. Therefore, the conditions of devices within the wafer can be monitored anytime. Besides, the passivation layer 106 is located on the dielectric layer 102 and only exposes the test pad 104 for preventing the devices from being affected by the external moisture.

Furthermore, after the test keys are inspected, the wafer is cut along the scribe lines of the wafer to form several chips by the diamond blade. Since the wafer is covered by various material layers, the material layers over the scribe liens split or delaminate due to different characteristics of the material layers while the wafer cutting process is performed. The phenomenon of delamination leads to introduction of the external moisture into the chips so that the reliability of the device is decreased or the devices within the chip are damaged.

For example, when the diamond blade is used to cut the wafer along the scribe lines, the test pad 104 is driven by the stress to squeezes on the passivation layer 106 so that the passivation layer 106 is delaminated. Accordingly, the die seal ring located outside the chip is damaged and the external moisture enters into the chips through the interface between the passivation layer 106 and the dielectric layer 102. Hence, the reliability of the devices on the chip is decreased.

### SUMMARY OF THE INVENTION

Accordingly, at least one objective of the present invention is to provide a semiconductor device capable of preventing the external moisture entering into devices on a chip during a wafer cutting process.

At least another objective of the present invention is to provide a method for forming a semiconductor device capable of preventing a film layer at a scribe line from being delaminated during a wafer cutting process.

The other objective of the present invention is to provide a semiconductor structure capable of prevent a die seal ring from being damaged during a wafer cutting process.

The objective of the present invention is to provide a method for manufacturing a semiconductor structure capable of improving the reliability of the devices on the chip.

To achieve these and other advantages and in accordance with the purpose of the invention, as embodied and broadly described herein, the invention provides a semiconductor structure located on a substrate in a scribe line region of a wafer. The semiconductor structure comprises a first dielectric layer, a first test pad and a passivation layer. The first dielectric layer is disposed on the substrate and the first test pad is disposed on the first dielectric layer. The passivation layer is disposed on the first dielectric layer and surrounding the first test pad and a groove is located between the first test pad and the passivation layer and the groove is at lest located between the boundary of the scribe line region and the first test pad.

In the semiconductor structure according to one embodiment of the present invention, the bottom of the groove is located in the first dielectric layer.

In the semiconductor structure according to one embodiment of the present invention, at least a second dielectric layer is located between the first dielectric layer and the substrate.

In the semiconductor structure according to one embodiment of the present invention, a second test pad is disposed at least on one of the second dielectric layers, wherein the second test pad is located under the first test pad.

In the semiconductor structure according to one embodiment of the present invention, the bottom of the groove exposes a surface of the second dielectric layer under the second test pad which is the nearest test pad to the substrate.

In the semiconductor structure according to one embodiment of the present invention, the bottom of the groove is located in the second dielectric layer under the second test pad which is the nearest test pad to the substrate.

In the semiconductor structure according to one embodiment of the present invention, the groove surrounds the first test pad.

In the semiconductor structure according to one embodiment of the present invention, the groove partially surrounds the first test pad.

The present invention also provides a method for forming a semiconductor structure. The method comprises providing a substrate having a scribe line region and then forming a first dielectric layer on the substrate. A first test pad is formed on the first dielectric layer in the scribe line region. A passivation layer is formed on the first dielectric layer to cover the first test pad. A first etching process is performed to remove a portion of the passivation layer over the first test pad so as to expose the first test pad and to form a groove between the sidewalls of the first test pad and the passivation layer and the groove is at least located between the first test pad and the boundary of the scribe line region.

In the method for forming the semiconductor structure according to one embodiment of the present invention, in the step of performing the first etching process, a portion of the first dielectric layer is removed so as to form the groove with the bottom in the first dielectric layer.

In the method for forming the semiconductor structure according to one embodiment of the present invention, before the first dielectric layer is formed, at least a second dielectric layer is formed on the substrate.

In the method for forming the semiconductor structure according to one embodiment of the present invention, a second test pad is formed on at least one of the second dielectric layers in the scribe line region and the second test pad is located under the first test pad.

In the method for forming the semiconductor structure according to one embodiment of the present invention, after the first etching process is performed, a second etching process is performed to remove the first dielectric layer and a portion of the second dielectric layer so as to form the groove with the bottom exposing a surface of the second dielectric layer under the second test pad which is the nearest test pad to the substrate.

In the method for forming the semiconductor structure according to one embodiment of the present invention, after the first etching process, a second etching process is performed to remove the first dielectric layer and a portion of the second dielectric layer so as to form the groove with the bottom in the second dielectric layer under the second test pad which is the nearest test pad to the substrate.

In the method for forming the semiconductor structure according to one embodiment of the present invention, the groove surrounds the first test pad.

In the method for forming the semiconductor structure according to one embodiment of the present invention, the groove partially surrounds the first test pad.

The present invention further provides a semiconductor structure located on a substrate in a scribe line region of a wafer. The semiconductor structure comprises a first dielectric layer, a first test pad and a passivation layer. The first dielectric layer is disposed on the substrate and the first test pad is disposed on the first dielectric layer. The passivation layer is disposed on the first dielectric layer and surrounding the first test pad and a plurality of grooves is located between the first test pad and the passivation layer and the grooves are at lest located between the boundary of the scribe line region and the first test pad.

The present invention provides a method for forming a semiconductor structure. The method comprises providing a substrate having a scribe line region and forming a first dielectric layer on the substrate. A first test pad is formed on the first dielectric layer in the scribe line region. A passivation layer is formed on the first dielectric layer to cover the first test pad. A first etching process is performed to remove a portion of the passivation layer over the first test pad so as to expose the first test pad and to form a plurality of grooves between the sidewalls of the first test pad and the passivation layer and the grooves are at least located between the first test pad and the boundary of the scribe line region.

In the present invention, since the groove is disposed between the test pad and the boundary of the scribe line region, the delamination of the film layer (such as the passivation layer or the dielectric layer) squeezed by the stress generated by the test pad during the wafer cutting process can be avoided. Furthermore, the devices in the device region can be prevented from being damaged by the external moisture entering into the device region through the interface between the film layers at the delamination portion. Hence, the device reliability is increased.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a cross-sectional view showing a conventional semiconductor structure located on the scribe line.

FIGS. 2A through 2C are cross-sectional views showing a method for manufacturing a semiconductor structure according to one embodiment of the present invention.

FIG. 3A is a top view of the semiconductor structure on a scribe line shown in FIG. 2C.

FIG. 3B is a top view of a semiconductor structure according to another embodiment of the present invention.

FIG. 3C is a top view of a semiconductor structure according to the other embodiment of the present invention.

FIG. 3D is a top view of a semiconductor structure according to the other embodiment of the present invention.

FIG. 3E is a top view of a semiconductor structure according to the other embodiment of the present invention.

FIG. 3F is a top view of a semiconductor structure according to the other embodiment of the present invention.

FIG. 3G is a top view of a semiconductor structure according to the other embodiment of the present invention.

FIG. 3H is a top view of a semiconductor structure according to the other embodiment of the present invention.

FIGS. 4A through 4C are cross-sectional views showing a method for manufacturing a semiconductor structure according to one embodiment of the present invention.

FIG. 5 is a cross-sectional view of a semiconductor structure according to another embodiment of the present invention.

### DESCRIPTION OF EMBODIMENTS

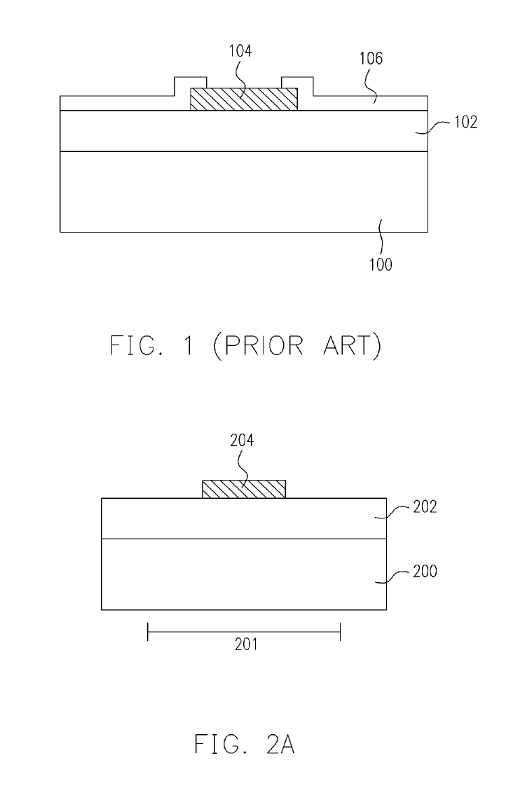

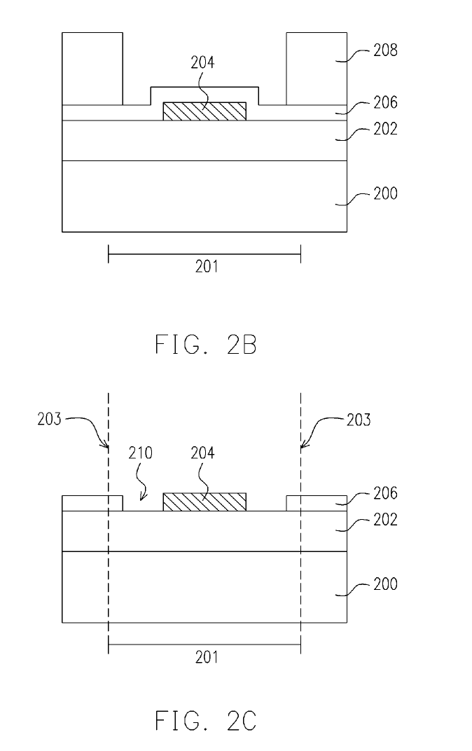

FIGS. 2A through 2C are cross-sectional views showing a method for manufacturing a semiconductor structure according to one embodiment of the present invention. As shown in FIG. 2A, a substrate 200 is provided. The substrate 200 has a scribe line region 201 and a device region (not shown). Then, a dielectric layer 202 is formed on the substrate 200. The dielectric layer 202 can be, for example, made of low-k material. Furthermore, within the dielectric layer 202 located in the scribe line region 201, there are interconnects structures or other device structures (not shown) which are as same as those formed in the dielectric layer 202 in the device region. These interconnects structures or other device structures are used as test keys. Thereafter, a test pad 204 is formed on the dielectric layer 202 in the scribe line region 201 and the test pad 204 is electrically connected to the aforementioned interconnects structures and other device structures so that the operator can use probe or other method to perform an inspection on the test key within the dielectric layer 202 in the scribe line region 201. Hence, the condition of the device in the device region can be monitored anytime. The material of the test pad 204 can be, for example, aluminum and the method for forming the test pad 204 can be, for example, comprise forming a pad material layer (not shown) on the dielectric layer 202 and then patterning the pad material layer.

As shown in FIG. 2B, a passivation layer 206 is formed on the dielectric layer 202 to cover the test pad 204. The passivation layer 206 can be, for example, made of silicon oxide, silicon nitride, silicon oxy-nitride or the well-known insulating material and the method for forming the passivation layer 206 can be, for example, a chemical vapor deposition. Then, a patterned photoresist layer 208 is formed on the passivation layer 206. The patterned photoresist layer 208 exposes a portion of the passivation layer 206 above the test pad 204 and a position for forming grooves in the later performed process.

As shown in FIG. 2C, by using the patterned photoresist layer 208 as a mask, an etching process is performed to remove the exposed portion of the passivation layer 206 over the test pad 204 and the position predetermined to form grooves so that the test pad 204 is exposed and a groove 210 between sidewalls of the passivation layer 206 and the test pad 204 at each side of the test pad 204 is formed. Moreover, the groove 210 is located between the test pad 204 and the boundary 203 of the scribe line region 201. The groove 210 exposes a portion of the surface of the dielectric layer 202. Then, the patterned photoresist layer 208 is removed.

It should be noticed that the steps for forming the aforementioned test pad 204, the test keys, the dielectric layer 202 and the passivation layer 206 is commonly integrated with the manufacturing process performed on the device region and it is unnecessary to further perform additional manufacturing steps. In addition, in the aforementioned etching process, not only the portion of the passivation layer 206 over the test pad 204 and the position predetermined to form grooves is removed but also a portion of the passivation layer 206 over the bonding pad in the device region is removed.

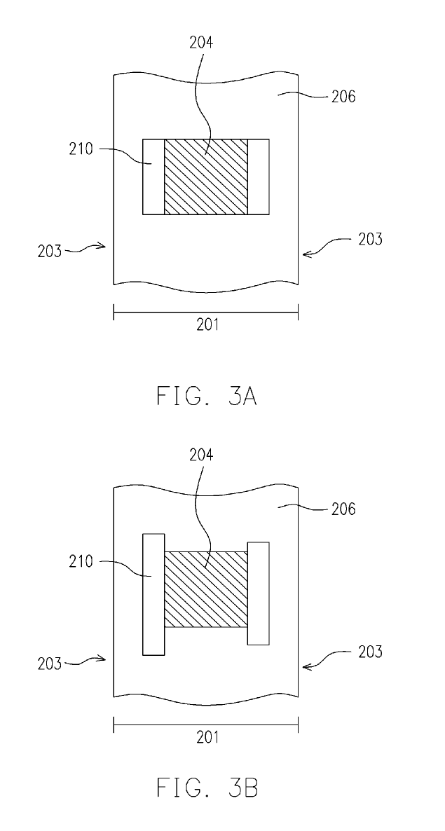

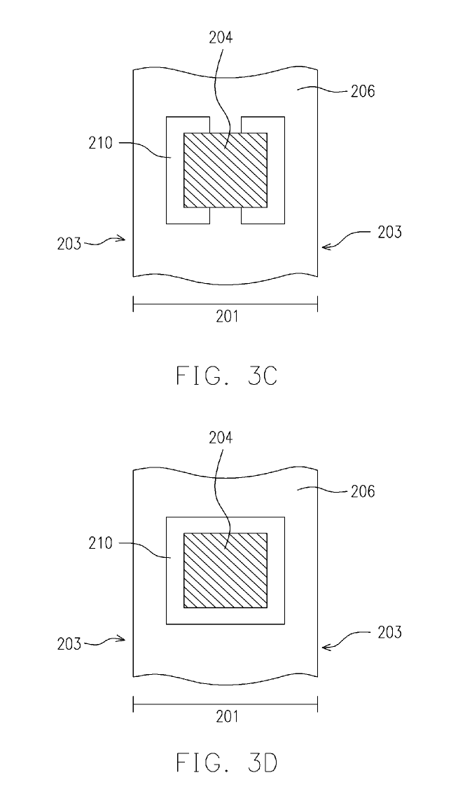

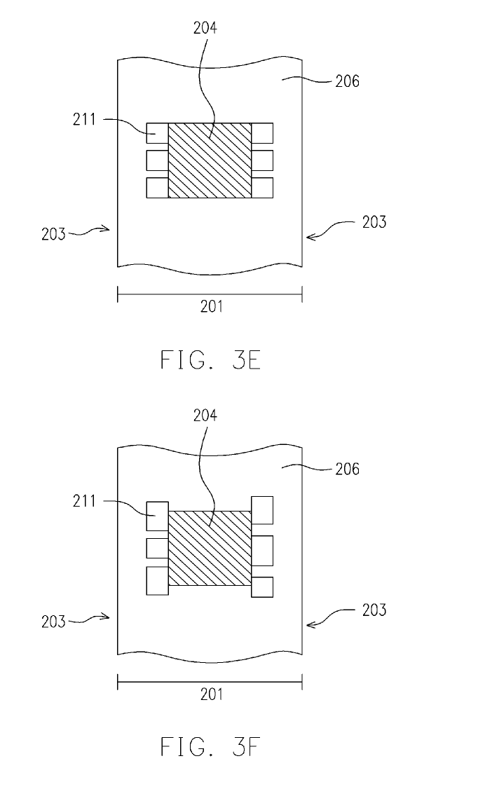

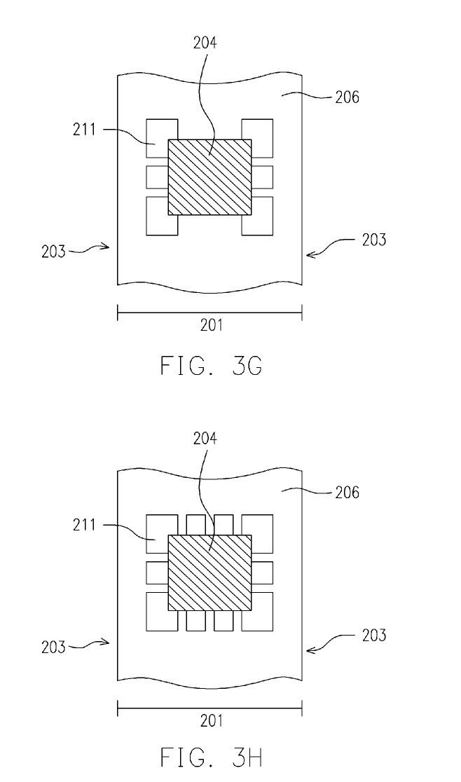

FIG. 3A is a top view of the semiconductor structure on a scribe line shown in FIG. 2C. FIG. 2C is taken as an example hereafter to describe the semiconductor structure of the present invention.

As shown in FIG. 3A together with FIG. 2C, the semiconductor structure of the present invention is located at the scribe line region 201 on the substrate 200. The semiconductor structure comprises the dielectric layer 202, the test pad 204 and the passivation layer 206. The dielectric layer 202 is disposed on the substrate 200 and the test pad 204 is located on the dielectric layer 202. The passivation layer 206 is located on the dielectric layer 202 and surrounding the test pad 204. Between the sidewalls of the passivation layer 206 and the test pad 204 at each side of the test pad 204, there is a groove 210 and the groove 210 is located between the test pad 204 and the boundary 203 of the scribe line region 201. In this embodiment, because the groove 210 is located between the passivation layer 206 and the test pad 204, that is, the extension direction of the groove 210 is along the cutting direction, the stress, which is generated from the test pad 204 as the test pad 204 is cut during the wafer cutting process, dose not impact the passivation layer 206 to be laminated. Furthermore, the problem that the external moisture enters into the device region through the interface between the passivation layer 206 and the dielectric layer 202 due to the delamination of the passivation layer can be avoided.

Additionally, in another embodiment, the bottom of the groove 210 can be located within the dielectric layer 202. That is, in the aforementioned etching process, not only a portion of the passivation layer 206 is removed but also a portion of the dielectric layer 202 is removed to form a groove 210 with a bottom inside the dielectric layer 202. Accordingly, the delamination of the passivation layer 206 due to the stress generated from the test pad 204 during the wafer cutting process can be avoided.

Furthermore, in the other embodiment, the shape of the groove 210 can be the shape shown in FIG. 3A and the opposite sides of the groove 210 which intersect with the cutting direction along the scribe line region 201 are at the same level with the opposite sides of the test pad 204, which intersect with the cutting direction along the scribe line region 201, respectively. Alternatively, the length of the groove 210, which is along the cutting direction following the scribe line region, can be larger than that of the test pad 204 and the lengths of the grooves 210 at both sides of the test pad 204 can be different from each other (as shown in FIG. 3B). In the other embodiment, the groove 210 not only can be disposed between the test pad 204 and the boundary 203 of the scribe line region 201 but also can be located adjacent to the test pad 204 and partially surrounding the test pad 204 (as shown in FIG. 3C) or fully surrounding the test pad 204 (as shown in FIG. 3D).

Notably, in the step for forming the groove 210 by using the etching process, besides using the patterned photoresist layer 208 as a mask to form the aforementioned groove 210, the patterned photoresist layer with different pattern can be also applied as a mask in the etching process so as to form several grooves 211 instead of the groove 210 at each side of the test pad 204. Moreover, the shape constituted by the grooves 211 at each of the opposite sides, which is parallel to the cutting direction along the scribe line region 201, can possess outmost sides, which intersect with the cutting direction along the scribe line region 201, at the same level with the opposite sides of the test pad 204, which intersect with the cutting direction along the scribe line region 201 (as shown in FIG. 3E). Alternatively, the length of the shape, which is along the cutting direction following the scribe line region, constituted by the grooves 211 can be larger than that of the test pad 204 (as shown in FIG. 3F). In the other embodiment, the shape constituted by the grooves 211 partially surrounds the test pad 204 (as shown in FIG. 3G) or fully surrounds the test pad 204 (as shown in FIG. 3H).

Additionally, in the FIG. 2A, before the dielectric layer 202 is formed, at least one dielectric layer 212 is formed on the substrate 200. The formation of two dielectric layers 212 over the substrate 200 is taken as an example in the following to describe the method for manufacturing a semiconductor structure of the present invention.

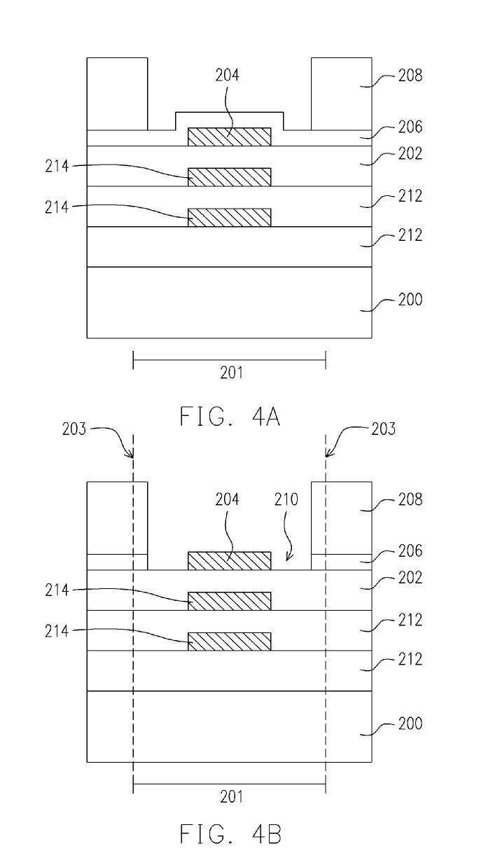

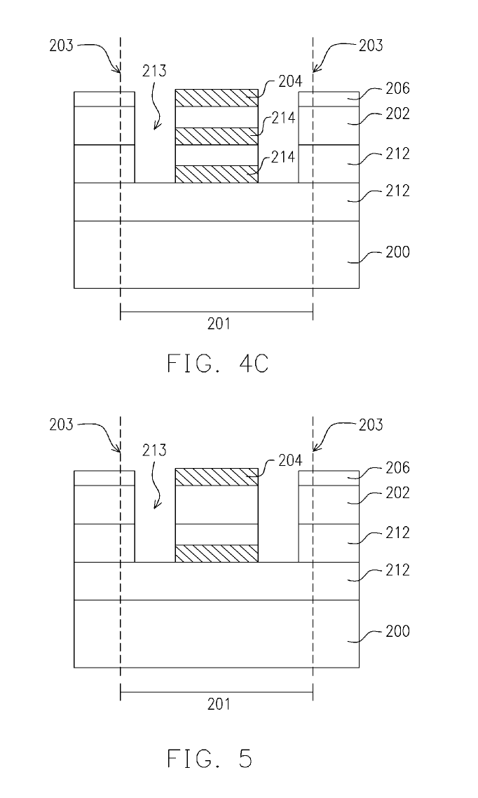

FIGS. 4A through 4C are cross-sectional views showing a method for manufacturing a semiconductor structure according to one embodiment of the present invention. As shown in FIG. 4A, a substrate 200 is provided. Then, a first dielectric layer 212 is formed on the substrate 200. The material of the first dielectric layer 212 can be, for example, a low-k material and, within the first dielectric layer 212 located in the scribe line region 201, there are test keys (not shown). Thereafter, a first test pad 214 is formed on the first dielectric layer 212 over the scribe line region 201 and the test pad 214 is electrically connected to the aforementioned test keys so that the operator can use probe or other method to perform the inspection. Moreover, a second dielectric layer 212 is formed on the first dielectric layer 212 and a second test pad 214 is formed on the second dielectric layer 212 over the scribe line region 201. Noticeably, in order to save the space to meet the requirement of the high integration, the second test pad 214 is normally formed right above the first test pad 214. Then, a dielectric layer 202 is formed on the second dielectric layer 212 and a test pad 204 is formed on the dielectric layer 202 over the scribe line region 201. Furthermore, the test pad 204 is located right above the second test pad 214. Further, a passivation layer 206 is formed on the dielectric layer 202 to cover the test pad 204. In addition, a patterned photoresist layer 208 is formed on the passivation layer 206 to expose a portion of the passivation layer 206 above the test pad 206 and the position for forming grooves in the later performed process.

As shown in FIG. 4B, by using the patterned photoresist layer 208 as a mask, an etching process is performed to remove the exposed passivation layer 206 over the test pad 204 and the position predetermined to form grooves to expose the test pad 204 and to form grooves 210 between the sidewalls of the passivation layer 206 and the test pad 204 at both sides of the test pad 204. Moreover, the groove 210 is located between the test pad 204 and the boundary 203 of the scribe line region 201 at each side of the test pad 204. The groove 210 exposes a portion of the surface of the dielectric layer 202.

As shown in FIG. 4C, by using the patterned photoresist layer 208 as a mask, another etching process is performed to remove a portion of the dielectric layer 202, a portion of the second dielectric layer 212 and a portion of the first dielectric layer 212 so as to form groove 213. In this embodiment, in order to prevent the dielectric layer 212 from being delaminated due to the stress generated from the test pad 214 under the test pad 204 during the wafer cutting process, the depth of the groove 213 should be large enough at least the bottom of the groove 213 at the same level with the surface of the dielectric layer 212 under the test pad 214, the first test pad 214, which is the nearest test pad to the substrate 200. Therefore, the dielectric layer 212, which is located under the nearest test pad to the substrate, can be prevented from being delaminated. That is, the bottom the groove 213 exposes the surface of the dielectric layer 212 under the nearest test pad 214 to the substrate 200. Alternatively, in another embodiment, to more efficiently prevent the dielectric layer 212 from being delaminated, the groove with relatively larger depth can be formed so that the bottom of the groove 213 is located within the dielectric layer 212 under the nearest test pad 214 to the substrate 200.

It should be noticed that the aforementioned two etching processes can be replaced by one etching process under the circumstance that the process factors of two etching processes are mutual compatible. That is, in the step illustrated by FIG. 4B, by using the patterned photoresist layer 208 as a mask, the groove 213 is directly formed by performing the etching process once.

Moreover, since the depth of the groove 213 is relatively large, the time for performing the etching process is relatively long. Therefore, the width of the upper opening of the groove 213 is relatively large because etching time is relatively long.

FIG. 3C is taken as an example hereafter to describe the semiconductor structure of the present invention.

As shown in FIG. 4C, the semiconductor structure of the present invention is located at the scribe line region 201 on the substrate 200. The semiconductor structure comprises the dielectric layers 202 and 212, the test pads 204 and 214 and the passivation layer 206. The dielectric layer 202 is disposed on the substrate 200 and the test pad 204 is located on the dielectric layer 202. The first dielectric layer 212 and the second dielectric layer 212 are disposed in order between the substrate 200 and the dielectric layer 202 and each layer of the dielectric layers 212 has a test pad 214 thereon. In addition, the test pads 214 are located under the test pad 204. The passivation layer 206 is located on the dielectric layer 202 and surrounding the test pad 204. Between the sidewalls of the passivation layer 206 and the test pad 204 at each side of the test pad 204, there is a groove 213 and the groove 213 is located between the test pad 204 and the boundary 203 of the scribe line region 201. The bottom of the groove 213 exposes the surface of the dielectric layer 212 under the test pad 214 which is the nearest test pad to the substrate 200. In another embodiment, to more efficiently prevent the dielectric layer 212 from being delaminated, the bottom of the groove 213 can be located within the dielectric layer 212 under the nearest test pad 214 to the substrate 200.

In the step illustrated by FIG. 4A, the test pad 214 can be selectively formed on the first dielectric layer 212 or on the second dielectric layer 212 in the scribe line region 201 according to the practical requirement.

For example, in one embodiment, the first dielectric layer 212 is formed on the substrate 200 beforehand. Then, the test pad 214 is formed on the first dielectric layer 212. Thereafter, the second dielectric layer 212 and the dielectric layer 202 are formed on the first dielectric layer 212 sequentially. Then, the test pad 204 and the passivation layer 206 are formed on the dielectric layer 202. A photolithography process and an etching process are performed to form the groove 213 and the bottom of the groove 213 is located at the surface of the first dielectric layer 212 or within the first dielectric layer 212. Hereafter, FIG. 5 is used to describe the semiconductor structure formed according to the method of this embodiment.

FIG. 5 is a cross-sectional view of a semiconductor structure according to another embodiment of the present invention. As shown in FIG. 5, the difference between the semiconductor structure of this embodiment differentiates and the semiconductor structure shown in FIG. 4C is that, in the semiconductor structure in FIG. 4C, the test pads 214 are disposed on the first dielectric layer 212 and the second dielectric layer 212 respectively and on the other hand, in the semiconductor structure of the present embodiment, the test pad 214 only disposed on the first dielectric layer 212. It should be noticed that, in this embodiment, although there is no test pad on the second dielectric layer 212, the bottom of the groove 213 still need to be located at the surface of the first dielectric layer 212 or within the first dielectric layer 212 as there is a test pad disposed on the first dielectric layer 212 so that the delamination of the first dielectric layer 212 during the wafer cutting process can be avoided.

Altogether, in the present invention, the groove is formed between the test pad and the boundary of the scribe line region so that the delamination of the film layer (such as the passivation layer or the dielectric layer) squeezed by the stress generated by the test pad during the wafer cutting process can be avoided. Furthermore, the devices in the device region can be prevented from being damaged by the external moisture entering into the device region through the interface between the film layers at the delamination portion. Hence, the device reliability is increased.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A semiconductor structure located on a substrate in a scribe line region of a wafer, the semiconductor structure comprising:
a first dielectric layer disposed on the substrate;
a first test pad disposed on the first dielectric layer; and
a passivation layer disposed on the first dielectric layer and surrounding the first test pad, wherein a groove is located between the first test pad and the passivation layer and the groove is at lest located between the boundary of the scribe line region and the first test pad.

2. The semiconductor structure of claim 1, wherein the bottom of the groove is located in the first dielectric layer.

3. The semiconductor structure of claim 1 further comprising at least a second dielectric layer located between the first dielectric layer and the substrate.

4. The semiconductor structure of claim 3 further comprising a second test pad disposed at least on one of the second dielectric layers, wherein the second test pad is located under the first test pad.

5. The semiconductor structure of claim 4, wherein the bottom of the groove exposes a surface of the second dielectric layer under the second test pad which is the nearest test pad to the substrate.

6. The semiconductor structure of claim 4, wherein the bottom of the groove is located in the second dielectric layer under the second test pad which is the nearest test pad to the substrate.

7. The semiconductor structure of claim 1, wherein the groove surrounds the first test pad.

8. The semiconductor structure of claim 1, wherein the groove partially surrounds the first test pad.

9. A method for forming a semiconductor structure, comprising:
providing a substrate having a scribe line region;
forming a first dielectric layer on the substrate;
forming a first test pad on the first dielectric layer in the scribe line region;
forming a passivation layer on the first dielectric layer to cover the first test pad; and
performing a first etching process to remove a portion of the passivation layer over the first test pad so as to expose the first test pad and to form a groove between the sidewalls of the first test pad and the passivation layer, wherein the groove is at least located between the first test pad and the boundary of the scribe line region.

10. The method of claim 9, wherein, in the step of performing the first etching process, a portion of the first dielectric layer is removed so as to form the groove with the bottom in the first dielectric layer.

11. The method of claim 9, wherein, before the first dielectric layer is formed, at least a second dielectric layer is formed on the substrate.

12. The method of claim 11 further comprising forming a second test pad on at least one of the second dielectric layers in the scribe line region and the second test pad is located under the first test pad.

13. The method of claim 12, wherein, after the first etching process is performed, a second etching process is performed to remove the first dielectric layer and a portion of the second dielectric layer so as to form the groove with the bottom exposing a surface of the second dielectric layer under the second test pad which is the nearest test pad to the substrate.

14. The method of claim 12, wherein, after the first etching process, a second etching process is performed to remove the first dielectric layer and a portion of the second dielectric layer so as to form the groove with the bottom in the second dielectric layer under the second test pad which is the nearest test pad to the substrate.

15. The method of claim 9, wherein the groove surrounds the first test pad.

16. The method of claim 9, wherein the groove partially surrounds the first test pad.

17. A semiconductor structure located on a substrate in a scribe line region of a wafer, the semiconductor structure comprising:
a first dielectric layer disposed on the substrate;
a first test pad disposed on the first dielectric layer; and
a passivation layer disposed on the first dielectric layer and surrounding the first test pad, wherein a plurality of grooves is located between the first test pad and the passivation layer and the grooves are at lest located between the boundary of the scribe line region and the first test pad.

18. The semiconductor structure of claim 17, wherein the bottoms of the grooves are located in the first dielectric layer.

19. The semiconductor structure of claim 17 further comprising at least a second dielectric layer disposed between the first dielectric layer and the substrate.

20. The semiconductor structure of claim 19 further comprising a second test pad located on at least one of the second dielectric layers and the second test pad is disposed under the first test pad.

21. The semiconductor structure of claim 20, wherein the bottoms of the grooves expose a portion of the surface of the second dielectric layer under the second test pad which is the nearest test pad to the substrate.

22. The semiconductor structure of claim 20, wherein the bottoms of the grooves are located in the second dielectric layer under the second test pad which is the nearest test pad to the substrate.

23. The semiconductor structure of claim 17, wherein the grooves surround the first test pad.

24. The semiconductor structure of claim 17, wherein the grooves partially surround the first test pad.

25. A method for forming a semiconductor structure, comprising:
providing a substrate having a scribe line region;
forming a first dielectric layer on the substrate;
forming a first test pad on the first dielectric layer in the scribe line region;
forming a passivation layer on the first dielectric layer to cover the first test pad; and
performing a first etching process to remove a portion of the passivation layer over the first test pad so as to expose the first test pad and to form a plurality of grooves between the sidewalls of the first test pad and the passivation layer, wherein the grooves are at least located between the first test pad and the boundary of the scribe line region.

26. The method of claim 25, wherein, in the first etching process, a portion of the first dielectric layer is removed to form the grooves with the bottoms in the first dielectric layer.

27. The method of claim 25, wherein, before the first dielectric layer is formed, at least a second dielectric layer is formed on the substrate.

28. The method of claim 27 further comprising forming a second test pad on at least one of the second dielectric layers in the scribe line region and the second test pad is disposed under the first test pad.

29. The method of claim 28, wherein, after the first etching process is performed, a second etching process is performed to remove the first dielectric layer and a portion of the second dielectric layer so as to form the grooves with the bottoms exposing a surface of the second dielectric layer under the second test pad which is the nearest test pad to the substrate.

30. The method of claim 28, wherein, after the first etching process is performed, a second etching process is performed to remove the first dielectric layer and a portion of the second dielectric layer so as to form the grooves with the bottoms located in the second dielectric layer under the second test pad which is the nearest test pad to the substrate.

31. The method of claim 25, wherein the grooves surround the first test pad.

32. The method of claim 25, wherein the grooves partially surround the first test pad.
